(19) United States
(12) Patent Application Publication
(10) Pub. No.: US 2024/0298787 A1
(43) Pub. Date: Sep. 12, 2024

(54) WAFER CLEANING BRUSH, WAFER CLEANING DEVICE INCLUDING THE SAME, AND WAFER CLEANING METHOD USING THE SAME

(71) Applicant: Samsung Electronics Co., Ltd., Suwon-si (KR)

(72) Inventors: Sanghyeok Kim, Suwon-si (KR); Jeongmin Na, Suwon-si (KR)

(73) Assignee: Samsung Electronics Co., Ltd., Suwon-si (KR)

(21) Appl. No.: 18/236,691

(22) Filed: Aug. 22, 2023

(30) Foreign Application Priority Data
Mar. 6, 2023 (KR) 10-2023-0029520

(51) Int. Cl. A46B 9/02; B08B 1/00; B08B 1/04

(52) U.S. Cl. CPC A46B 9/026; B08B 1/12; B08B 1/32; A46B 2200/3073

(57) ABSTRACT

A wafer cleaning brush includes a rotatable core, a brush body surrounding an outer circumferential surface of the core, and a plurality of protrusions disposed on a brush body surface, where a pitch of the plurality of protrusions in a length direction of the brush body may be in a range of 11 mm to 15 mm, and where, for each of the plurality of protrusions, a value obtained by dividing a long side of the brush body in the length direction by the pitch is below 0.55.

### CROSS-REFERENCE TO RELATED APPLICATION

This application claims priority to and the benefit of Korean Patent Application No. 10-2023-0029520 filed in the Korean Intellectual Property Office on Mar. 6, 2023, the entire contents of which are incorporated herein by reference.

### BACKGROUND

### 1. Field

The present disclosure relates to a wafer cleaning brush, a wafer cleaning device including the same, and a wafer cleaning method using the same.

### 2. Description of the Related Art

Integrated circuits are generally formed by successive deposition of conductors, semiconductors, or insulators on a substrate, particularly a silicon wafer. After each layer is deposited, each layer is etched to impart circuit characteristics. As successive layers are deposited and etched, the exposed surface of the wafer becomes increasingly rough, and a chemical mechanical polishing process (CMP) is used to smooth the wafer.

After such a chemical mechanical polishing process (CMP), particles such as polishing by-products and slurry remain on the surface of the wafer. Therefore, a cleaning process is performed on the surface of the wafer to remove particles such as the polishing by-products and slurry.

The cleaning process may be performed using a brush having an excellent particle removal effect. However, brushes currently used in the cleaning process have a disadvantage in that cleaning may be performed non-uniformly because the area in contact with the wafer is not uniform.

### SUMMARY

The present disclosure attempts to provide a wafer cleaning brush, a wafer cleaning device including the same, and a wafer cleaning method using the same that is capable of uniformly cleaning a wafer surface from a center to an edge.

According to an aspect of the disclosure, a wafer cleaning brush includes: a rotatable core; a brush body surrounding an outer circumferential surface of the core; and a plurality of protrusions disposed on a surface of the brush body, wherein each of the plurality of protrusions comprises a width measured in a length direction of the brush body, wherein a pitch of the plurality of protrusions in the length direction of the brush body is in a range of 11 mm to 15 mm, and wherein, for each of the plurality of protrusions, a value obtained by dividing the width of the protrusion by the pitch is less than 0.55.

The width of each of the plurality of protrusions may be in a range of 5 mm to 8 mm.

The pitch of the plurality of protrusions in the length direction of the brush body may be in a range of 11 mm to 13 mm, and for each of the plurality of protrusions, the value obtained by dividing the width of the protrusion by the pitch may be in a range of 0.515 to 0.525.

The width of each of the plurality of protrusions may be in a range of 5.5 mm to 7.0 mm.

The pitch of the plurality of protrusions in the length direction of the brush body may be in a range of 14 mm to 15 mm, and for each of the plurality of protrusions, the value obtained by dividing the width of the protrusion by the pitch may be in a range of 0.505 to 0.515.

The width of each of the plurality of protrusions may be in a range of 7 mm to 8 mm.

A height of each of the plurality of protrusions may be in a range of 1 mm to 5 mm.

A horizontal cross-sectional shape of each of the plurality of protrusions may be one of a circular shape, a rectangular shape, an oval shape, and a polygonal shape.

A quantity A of the plurality of protrusions disposed in the length direction of the brush body may satisfy Equation 1: (P(A−1)+P/2)+D<L, wherein P is the pitch of the plurality of protrusions in the length direction of the brush body, D is the width of each of the plurality of protrusions in the length direction of the brush body, and L is a length of the brush body.

The wafer cleaning brush may include a cylindrical shape having a circular bottom and a height, and based on a cross-section cut parallel to the circular bottom, a quantity B of the plurality of protrusions may satisfy Equation 2: √(P\hat{ }2/4+(πr/B)\hat{ }2)>D, wherein P is the pitch of the plurality of protrusions in the length direction of the brush body, D is the width of each of the plurality of protrusions in the length direction of the brush body, and r is a radius of the brush body.

The quantity B of the plurality of protrusions may be in a range of 12 to 20.

An interval of the plurality of protrusions in the length direction of the brush body may be in a range of 5 mm to 8 mm.

According to an aspect of the disclosure, a wafer cleaning device includes: a pair of brushes respectively disposed on an upper surface of a wafer and a lower surface of the wafer, wherein each of the pair of brushes comprises: a rotatable core; a brush body surrounding an outer circumferential surface of the core; and a plurality of protrusions each disposed on a surface of the brush body and comprising a circular horizontal cross-section, wherein each of the plurality of protrusions comprises a width measured in a length direction of the brush body, wherein a pitch of the plurality of protrusions in the length direction of the brush body is in a range of 11 mm to 15 mm, and wherein, for each of the plurality of protrusions, a value obtained by dividing the width of the protrusion by the pitch is in a range of 0.505 to 0.525.

The brush body may include a cylindrical shape having a circular bottom and a height, and based on a cross-section cut parallel to the bottom, a quantity of the plurality of protrusions may be in a range of 12 to 20.

A height of each of the plurality of protrusions may be in a range of 1 mm to 5 mm.

According to an aspect of the disclosure, a wafer cleaning method includes: providing a wafer having undergone a chemical mechanical planarization process; disposing a wafer cleaning brush on an upper surface of the wafer, wherein the wafer cleaning brush includes a plurality of protrusions on a surface of the wafer cleaning brush; supplying a cleaning composition to the upper surface of the wafer; and removing particles on the upper surface of the wafer by bringing the plurality of protrusions into contact with the upper surface of the wafer, wherein in the removing of the particles, the wafer and the wafer cleaning brush respectively rotate, and a maximum value of the contact frequency between the plurality of protrusions and the wafer surface is less than or equal to 0.90.

A maximum value of the contact frequency between the plurality of protrusions and the wafer surface may be in a range of 0.50 to 0.80.

A value obtained by dividing a maximum value of the contact frequency between the plurality of protrusions and the wafer surface by a minimum value of the contact frequency may be in a range of 110 to 155.

A rotation speed of the wafer may be in a range of 1 rpm to 150 rpm.

A rotation speed of the wafer cleaning brush may be in a range of 1 rpm to 400 rpm.

According to an aspect of the disclosure, a wafer cleaning device includes: a plurality of support rollers configured to support a wafer and to rotate the wafer around an axis of rotation; a cleaning solution supply nozzle configured to supply a cleaning solution to at least one of an upper surface of the wafer and a lower surface of the wafer; and a pair of brushes respectively disposed on an upper surface of the wafer and a lower surface of the wafer, wherein each of the pair of brushes includes: a rotatable brush body; and a plurality of protrusions disposed on a surface of the brush body, wherein each of the plurality of protrusions includes a width measured in a length direction of the brush body, wherein a pitch of the plurality of protrusions in the length direction of the brush body is in a range of 11 mm to 15 mm, and wherein, for each of the plurality of protrusions, a value obtained by dividing the width of the protrusion by the pitch is less than 0.55.

A wafer cleaning method according to an embodiment includes providing a wafer having undergone a chemical mechanical planarization process, disposing a wafer cleaning brush formed with a plurality of protrusions on a surface on an upper surface of the wafer, supplying a cleaning composition to the wafer, and removing particles on a wafer surface by bringing the plurality of protrusions into contact with the wafer surface supplied with the cleaning composition, where in the removing of the particle, the wafer and the wafer cleaning brush respectively rotate, and a maximum value of the contact frequency between the plurality of protrusions and the wafer surface is less than or equal to 0.90.

A maximum value of the contact frequency between the plurality of protrusions and the wafer surface may be in a range of 0.50 to 0.80.

A value obtained by dividing a maximum value of the contact frequency between the plurality of protrusions and the wafer surface by a minimum value of the contact frequency may be in a range of 110 to 155.

In the removing of the particle, a rotation speed of the wafer may be in a range of 1 rpm to 150 rpm.

A rotation speed of the wafer cleaning brush may be in a range of 1 rpm to 400 rpm.

When the cleaning process is performed by using a wafer cleaning brush according to embodiments, uniform cleaning is possible since the contact may be uniform from the center to the edge of the wafer surface.

In addition, since cleaning is uniformly performed even in the chemical-mechanical polishing process of the metal thin film, occurrence of corrosion in the metal thin film may be very effectively prevented.

The various beneficial advantages and effects of the present disclosure are not limited to the above description, and will be more easily understood in the process of describing specific embodiments of the present disclosure.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 schematically illustrates a wafer cleaning device according to an embodiment;

FIG. 2 schematically illustrates a wafer cleaning brush according to an embodiment;

FIG. 3 is a cross-sectional view of the wafer cleaning brush in FIG. 2 along a plane of D2-D3;

FIG. 4 is a cross-sectional view of the wafer cleaning brush in FIG. 2 along a plane of D1-D3;

FIG. 5 schematically illustrates a wafer cleaning brush according to another embodiment; and

FIG. 6 is a cross-sectional view of the wafer cleaning brush in FIG. 5 along a plane of D2-D3.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

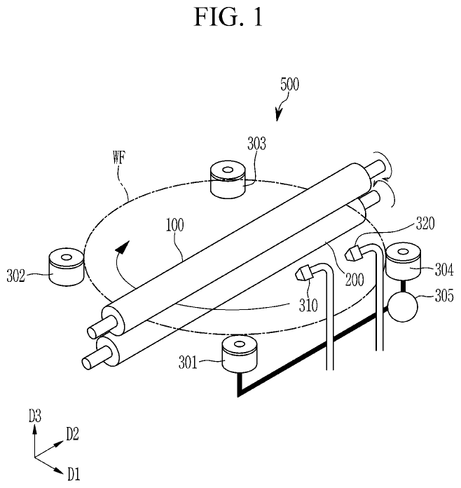

FIG. 1 schematically illustrates a wafer cleaning device according to an embodiment.

Referring to FIG. 1, a wafer cleaning device 500 according to an embodiment is used in a cleaning process of a semiconductor wafer WF. As described above, particles such as polishing by-products and slurry remain on a wafer surface after a chemical mechanical polishing process (CMP).

The wafer cleaning device 500 of the present embodiment includes a pair of wafer cleaning brushes 100 and 200 that are disposed to face each other on an upper surface and a lower surface of the wafer WF.

The wafer cleaning device 500 is also provided with a lower roll arm configured to rotatably support a wafer cleaning brush 200 positioned on the lower surface of the wafer WF. The lower roll arm may be configured, for example, in an upside down mirror configuration of an upper roll arm such that the wafer cleaning brush 200 slidably contacts the lower surface of the wafer WF.

As shown in FIG. 1, the wafer cleaning device 500 includes four support rollers 301, 302, 303, and 304 configured to support and rotate the wafer WF after being horizontally disposed, the pair of wafer cleaning brushes 100 and 200 in the cylindrical shape that are respectively in contact with the upper and lower surfaces of the wafer WF, upper cleaning solution supply nozzles 310 and 320 configured to supply a cleaning solution to the surface of the wafer WF. The wafer cleaning device 500 includes a lower cleaning solution supply nozzle configured to supply the cleaning solution to the lower surface of the wafer WF.

The support rollers 301, 302, 303, and 30 are configured movable by a driving device (for example, an air cylinder) along directions approaching and away from the wafer WF. Two support rollers 301 and 304 among the four support rollers are connected to a wafer rotating device 305, and the two support rollers 301 and 304 are to be rotated in the same direction by the wafer rotating device 305. In an embodiment, the wafer rotating device 305 may be provided in a plural quantity, to be connected to each of the support rollers 301, 302, 303, and 304. In a state of supporting the wafer WF by the four support rollers 301, 302, 303, and 304, the wafer WF may rotate around its rotation axis as the two support rollers 301 and 304 rotate. In the present embodiment, wafer supporting portion to support and rotate the wafer WF mainly includes the support rollers 301, 302, 303, and 304 and the wafer rotating device 305.

In the cleaning process, while rotating the wafer WF in a horizontal direction, the cleaning solution is supplied to the surface of the wafer WF, and the pair of wafer cleaning brushes 100 and 200 are also rotated and brought into contact with the surface of the wafer WF. Accordingly, particles remaining on the surface of the wafer WF may be removed.

An entire length of each of the pair of wafer cleaning brushes 100 and 200 may be slightly longer than diameter of the wafer WF. In addition, a central axis (rotation axis) of each of the pair of wafer cleaning brushes 100 and 200 is disposed substantially orthogonal to the rotational axis of the wafer WF. In this case, the wafer WF and the wafer cleaning brush 100 positioned on the upper surface of the wafer WF are in contact with each other in a cleaning area that extends in a straight line over the entire diameter direction of the wafer WF. Accordingly, the wafer cleaning brush 100 positioned on the upper surface of the wafer WF may simultaneously clean the entire surface of the wafer WF. This is the same for the wafer cleaning brush 200 positioned on the lower surface of the wafer WF. In this way, since the wafer WF and the pair of wafer cleaning brushes 100 and 200 rotate together, efficient cleaning of the wafer WF is possible.

In addition, the cleaning solution supplied while cleaning the wafer WF may be one of, for example, ultrapure water (DI water), ammonia water (NH4OH), or hydrofluoric acid (HF), but is not limited thereto.

The method of removing particles remaining on the wafer by using a brush as in this embodiment is the most effective method in terms of cleaning capability. However, the brush currently used in the cleaning process has a disadvantage in that uniform cleaning is difficult because the difference between the contact frequency with the center portion of the wafer and the contact frequency with the edge portion is very large during the cleaning process. In particular, in the chemical-mechanical polishing process of the metal thin film, when the central portion of the wafer is contacted more, a defect in which the oxide film is peeled off and the metal is lost may occur. In the present embodiment, it is possible to provide a wafer cleaning device capable of improving contact uniformity by minimizing the contact frequency in which the brush contacts the central portion of the wafer surface during the cleaning process.

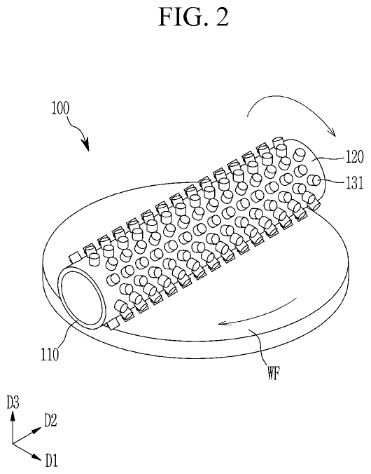

Hereinafter, a wafer cleaning brush according to an embodiment is described in detail with reference to FIG. 2 to FIG. 4.

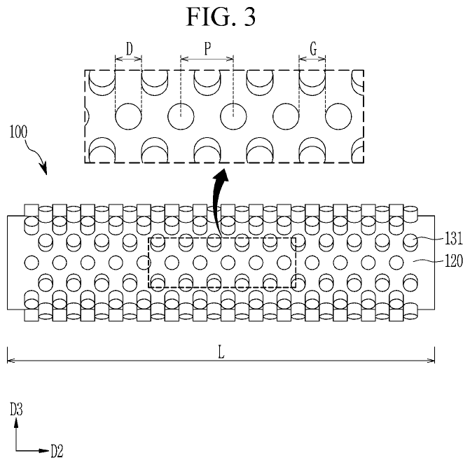

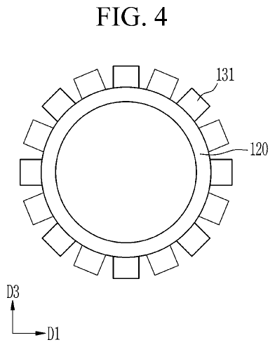

FIG. 2 schematically illustrates a wafer cleaning brush according to an embodiment. FIG. 3 is a cross-sectional view of the wafer cleaning brush in FIG. 2 along a plane of D2-D3. FIG. 4 is a cross-sectional view of the wafer cleaning brush in FIG. 2 along a plane of D1-D3.

Referring to FIG. 2 to FIG. 4, a wafer cleaning brush 100 according to an embodiment may include a rotatable core 110, a brush body 120 surrounding an outer circumferential surface of the core, and a plurality of protrusions 131 disposed on a brush body surface.

The core 110 is rotatable, and may be made of a material such as, for example, Teflon. In addition, the brush body 120 has a porous structure, and may be made of, for example, a resin such as polyvinyl alcohol (PVA) or nylon.

The plurality of protrusions 131 are formed on the surface, that is, the outer circumferential surface, of the brush body 120. The plurality of projections may be manufactured in a manner such as 3D printing using the same material as the brush body 120, and it is also possible that, after the brush body 120 is manufactured first, the plurality of protrusions are additionally formed on the surface of the brush body 120. When the protrusions are included in this way, the cleaning capability may be further improved.

A horizontal cross-sectional shape of each of the plurality of protrusions may be one of a circular shape, a rectangular shape, an oval shape, and a polygonal shape. In this embodiment, the horizontal cross-sectional shape of each protrusion may be circular. That is, each of the protrusions 131 may be disposed on a surface of the brush body 120 by protruding in a cylindrical shape.

Referring to FIG. 3, the plurality of protrusions 131 may be aligned and arranged at equal intervals in a line in the length direction (direction D2) of the brush body 120.

In an embodiment, a pitch P of the plurality of protrusions 131 may be 11 mm to 15 mm. The pitch P is a distance from a center of each protrusion to a center of a neighboring protrusion. The width D of each protrusion 131 in the length direction (D2 direction) may be in a range of 5 mm to 8 mm. In addition, a value obtained by dividing the width D in the length direction by the above-mentioned pitch P for each of the protrusions 131 may be below 0.55, more specifically, in a range of 0.48 to 0.55.

In another embodiment, the pitch P of the plurality of protrusions 131 in the length direction (D2 direction) of the brush body 120 may be in a range of 11 mm to 13 mm, and the width D of each protrusion 131 in the length direction (D2 direction) may be in a range of 5.5 mm to 7.0 mm.

In addition, for each of the plurality of protrusions 131, the value obtained by dividing the width D in the length direction (D2 direction) by the pitch P may be in a range of 0.505 to 0.525 or in a range of 0.515 to 0.525.

In another embodiment, the pitch P of the plurality of protrusions 131 in the length direction (D2 direction) of the brush body 120 may be in a range of 14 mm to 15 mm, and the width D of each protrusion 131 in the length direction (D2 direction) may be in a range of 7 mm to 8 mm.

For each of the plurality of protrusions 131, the value obtained by dividing the width D in the length direction (D2 direction) by the pitch P may be in a range of 0.505 to 0.525 or in a range of 0.505 to 0.515.

Meanwhile, an interval G of the plurality of protrusions 131 in the length direction (D2 direction) of the brush body 120 may be in a range of 5 mm to 8 mm.

In this embodiment, when the pitch P of the plurality of protrusions, the width D of each of the protrusions, and the value (D/P) obtained by dividing the width by the pitch satisfy corresponding ranges, a maximum value of the contact frequency of the central portion of the surface of the wafer WF may be minimized. Accordingly, in the cleaning process in which the brush protrusion 131 contacts the surface of the wafer WF, contact uniformity of the brush protrusion 131 with respect to the wafer WF may be improved.

In addition, a height of each of the plurality of protrusions 131 may be, for example, in a range of 1 mm to 5 mm, but the disclosure is not limited thereto.

A quantity A of the plurality of protrusions 131 disposed in the length direction (D2 direction) of the brush body 120 may satisfy Equation 1 below.

$$( P ( A - 1 ) + P / 2 ) + D < L \qquad Equation 1$$

In Equation 1, P is the pitch of the plurality of protrusions 131 in the length direction (D2 direction) of the brush body 120, D is a width of each of the protrusions 131 in the length direction (D2 direction) of the brush body 120, and L is a length of the brush body 120.

When the quantity of the protrusions 131 disposed in the length direction (D2 direction) of the brush body 120 satisfies Equation 1, efficient cleaning is possible by using the wafer cleaning brush 100 of the present embodiment.

The wafer cleaning brush 100 has a cylindrical shape having a circular bottom and a height. Based on a cross-section cut parallel to the bottom of the cylindrical shape, a quantity B of the plurality of protrusions 131 may satisfy Equation 2 below.

$$√ ( {P}^{∧} 2 / 4 + {( π r / B )}^{∧} 2 ) > D \qquad Equation 2$$

In Equation 2, P is the pitch of the plurality of protrusions 131 in the length direction (D2 direction) of the brush body 120, D is the width of each of the protrusions 131 in the length direction (D2 direction) of the brush body 120, and r is a radius of the brush body 120.

The quantity B of the plurality of protrusions 131 calculated by Equation 2 may be, for example, in a range of 12 to 20 range.

Referring to FIG. 4, when the quantity of the protrusions 131 disposed in the circumferential direction of the brush body 120 in the plane of D1-D3 satisfies Equation 2, efficient cleaning is possible by using the wafer cleaning brush 100 of the present embodiment.

In this embodiment, each of the protrusions 131 is in a cylindrical shape, and has a circular horizontal cross-section. Therefore, in this embodiment, the pitch P of the plurality of protrusions 131 is a distance between centers of neighboring protrusions 131, and the width D in the length direction (D2 direction) of the brush body 120 is a diameter of the circle.

In addition, in the present specification, a circular region from center of the surface of the circular wafer WF to ⅓ of the radius of the wafer WF is called a central portion, a donut-shaped region from the ⅓ of the radius of the wafer WF to ⅔ of the radius of the wafer WF is called a middle portion, and a donut-shaped region from the ⅔ of the radius of the wafer W to the edge is called an edge portion.

Hereinafter, other embodiments will be described with reference to the drawings. In embodiments to be described below, similar features as those of the previous embodiments will be omitted and differences therebetween will be mainly described. In addition, same reference numerals are used for same components as in the previous embodiment.

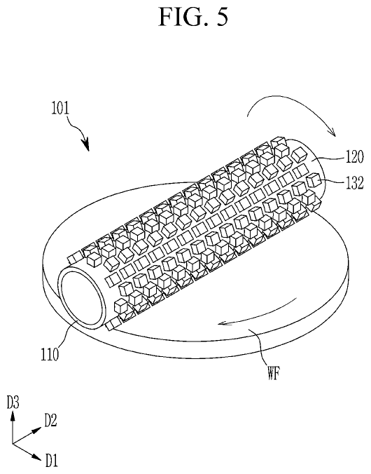

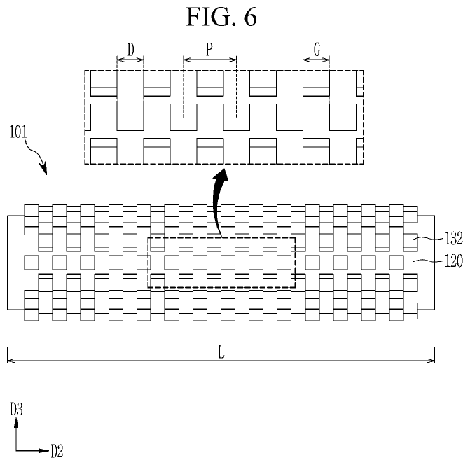

FIG. 5 schematically illustrates a wafer cleaning brush according to another embodiment. FIG. 6 is a cross-sectional view of the wafer cleaning brush in FIG. 5 along a plane of D2-D3.

Shapes of a plurality of protrusions 132 of a wafer cleaning brush 101 in the present embodiment differ from those of the embodiment described in connection with FIG. 2 to FIG. 4.

Referring to FIG. 5 and FIG. 6, in this embodiment, each protrusion 132 has a hexahedral shape and its horizontal cross-section is rectangular. Therefore, in this embodiment, a pitch P of the plurality of protrusions 132 is a distance between rectangular centers of neighboring protrusions 132, and the width D in the length direction (D2 direction) of the brush body 120 is the length of the side in the D2 direction of the rectangle.

In this embodiment, the hexahedron-shaped protrusion 132 may be, for example, a rectangular parallelepiped in which the areas of an upper surface in contact with the brush body and a lower surface opposite to the upper surface of the protrusion are the same, or a regular hexahedron having the same area on each side, or a hexahedral shape in which an area of an upper surface is larger or smaller than an area of a lower surface.

A wafer cleaning method according to an embodiment may include providing a wafer having undergone a chemical mechanical planarization process, disposing a wafer cleaning brush formed with a plurality of protrusions on a surface on an upper surface of the wafer, supplying a cleaning composition to the wafer, and removing particles on a wafer surface by bringing the plurality of protrusions into contact with the wafer surface supplied with the cleaning composition.

First, a wafer having undergone a chemical mechanical planarization process is provided in order to remove particles such as polishing by-products and slurry.

Then, the provided wafer is rotated about its central axis (rotational axis), and the wafer cleaning brush is placed such that the central axis of the wafer and the rotational axis of the brush are orthogonal.

Thereafter, the cleaning composition is supplied to the wafer through the cleaning solution supply nozzle.

In this state, removal of the particles is performed while rotating the wafer cleaning brush such that the plurality of protrusions located on the surface of the wafer cleaning brush are brought into contact with the surface of the wafer.

Here, details of the wafer cleaning brush are the same as have been described above, and thus are not described again.

In addition, in the removing of the particles, the wafer and the wafer cleaning brush are respectively rotated. That is, since the wafer and the wafer cleaning brush simultaneously rotate, the cleaning process may be performed more efficiently.

In an embodiment, a maximum value of the contact frequency between the wafer surface and the plurality of protrusions disposed on the surface of the wafer cleaning brush may be less than or equal to 0.90, more specifically, in a range of 0.50 to 0.80 or in a range of 0.55 to 0.78.

In addition, a value obtained by dividing a maximum value of the contact frequency between the plurality of protrusions and the wafer surface by a minimum value of the contact frequency may be in a range of 110 to 155, more specifically, in a range of 120 to 150 or in a range of 121 to 148.

In more detail, in the removing of the particles, a rotation speed of the wafer may be in a range of 1 rpm to 150 rpm, or in a range of 50 rpm to 150 rpm.

In addition, a rotation speed of the wafer cleaning brush may be in a range of 1 rpm to 400 rpm or in a range of 50 rpm to 400 rpm.

In addition, the process of bringing the plurality of protrusions into contact with the wafer surface supplied with the cleaning composition may be performed by applying a downforce of 1 N to 3 N of the wafer cleaning brush toward the wafer surface.

In this way, when the cleaning process is performed by applying the wafer cleaning brush according to an embodiment, the maximum value of the contact frequency between the wafer surface and the plurality of protrusions disposed on the brush may be significantly decreased, and accordingly, by improving contact uniformity between the brush and the wafer surface, uniform cleaning over the central portion, the middle portion, and the edge portion of the wafer surface may be possible.

Hereinafter, embodiments of the present disclosure will be described in detail. However, it may be understood that, since these are merely examples, the scope of the present disclosure is not limited thereto, and may be understood by the claims.

### Embodiments 1 to 5 and Comparative Examples 1 to 2

Wafer cleaning brushes according to Comparative Examples 1 to 2 and Embodiments 1 to 5 in which cylindrical protrusions were disposed on the surface to have pitches, diameters, and intervals as shown in Table 1 were manufactured.

TABLE 1

| | Protrusion | Protrusion | Protrusion | Protrusion |
|---|---|---|---|---|
| | pitch P | diameter (D) | interval G | diameter: |
| Category | (mm) | (mm) | (G = P − D) | pitch |
| Comparative | 13.3 | 7.30 | 6.00 | D = 0.55 P |
| Example 1 | | | | |
| Comparative | 13.5 | 7.50 | 6.00 | D = 0.56 P |
| Example 2 | | | | |
| Embodiment 1 | 11.0 | 5.72 | 5.28 | D = 0.52 P |
| Embodiment 2 | 12.0 | 6.24 | 5.76 | D = 0.52 P |
| Embodiment 3 | 13.0 | 6.63 | 6.24 | D = 0.51 P |
| Embodiment 4 | 14.0 | 7.14 | 6.86 | D = 0.51 P |
| Embodiment 5 | 15.0 | 7.65 | 7.35 | D = 0.51 P |

### Experimental Example

In order to check the contact uniformity of the wafer cleaning brushes manufactured according to Examples 1 to 5 and Comparative Examples 1 to 2, a test for checking the maximum and minimum values of the contact frequency between the protrusions and the wafer surface is performed under the following conditions, and the results are shown in Table 2, below.
1. Cleaning period: 30 seconds
2. Wafer rotation speed: 53 rpm
3. Rotation speed of wafer cleaning brush: 302 rpm
4. Length of brush body: 308 mm
5. Diameter of brush body: 53.2 mm
6. Downforce: 2 N
7. Protrusion height: 3 mm
8. Quantity of protrusions positioned along the circumferential direction of the brush body: 16
9. Quantity of protrusions positioned in the length direction of the brush body: 24

TABLE 2

| | | Maximum value/minimum |
|---|---|---|
| | Maximum value of contact | value of contact frequency |
| | frequency between wafer | between wafer surface and |
| Category | surface and protrusions | protrusions |
| Comparative | 0.99 | 165.5 |
| Example 1 | | |
| Comparative | 0.99 | 184.9 |
| Example 2 | | |
| Embodiment 1 | 0.78 | 122.1 |
| Embodiment 2 | 0.75 | 136.3 |
| Embodiment 3 | 0.61 | 121.2 |
| Embodiment 4 | 0.60 | 147.9 |
| Embodiment 5 | 0.55 | 146.0 |

Referring to Table 1 and Table 2, in comparison with Comparative Example 1 and Comparative Example 2 where the value (D/P) obtained by dividing the pitch of the plurality of protrusions by the protrusion diameter is greater than or equal to 0.55, Embodiments 1 to 5 where the D/P value is less than or equal to 0.55 show that the maximum value of the contact frequency between the protrusions and the wafer surface is significantly decreased, and in addition, the value obtained by dividing the maximum value of the contact frequency by the minimum value of the contact frequency is also decreased by 15% at minimum to almost 40% at maximum.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A wafer cleaning brush comprising:
a rotatable core;
a brush body surrounding an outer circumferential surface of the core; and
a plurality of protrusions disposed on a surface of the brush body,
wherein each of the plurality of protrusions comprises a width measured in a length direction of the brush body,
wherein a pitch of the plurality of protrusions in the length direction of the brush body is in a range of 11 mm to 15 mm, and
wherein, for each of the plurality of protrusions, a value obtained by dividing the width of the protrusion by the pitch is less than 0.55.

2. The wafer cleaning brush of claim 1, wherein the width of each of the plurality of protrusions is in a range of 5 mm to 8 mm.

3. The wafer cleaning brush of claim 1, wherein:
the pitch of the plurality of protrusions in the length direction of the brush body is in a range of 11 mm to 13 mm, and
for each of the plurality of protrusions, the value obtained by dividing the width of the protrusion by the pitch is in a range of 0.515 to 0.525.

4. The wafer cleaning brush of claim 1, wherein the width of each of the plurality of protrusions is in a range of 5.5 mm to 7.0 mm.

5. The wafer cleaning brush of claim 1, wherein:
the pitch of the plurality of protrusions in the length direction of the brush body is in a range of 14 mm to 15 mm, and
for each of the plurality of protrusions, the value obtained by dividing the width of the protrusion by the pitch is in a range of 0.505 to 0.515.

6. The wafer cleaning brush of claim 1, wherein the width of each of the plurality of protrusions is in a range of 7 mm to 8 mm.

7. The wafer cleaning brush of claim 1, wherein a height of each of the plurality of protrusions is in a range of 1 mm to 5 mm.

8. The wafer cleaning brush of claim 1, wherein a horizontal cross-sectional shape of each of the plurality of protrusions is one of a circular shape, a rectangular shape, an oval shape, and a polygonal shape.

9. The wafer cleaning brush of claim 1, wherein a quantity A of the plurality of protrusions disposed in the length direction of the brush body satisfies Equation 1 below:
$$( P ( A - 1 ) + P / 2 ) + D < L \qquad Equation 1$$
wherein P is the pitch of the plurality of protrusions in the length direction of the brush body, D is the width of each of the plurality of protrusions in the length direction of the brush body, and L is a length of the brush body.

10. The wafer cleaning brush of claim 1, wherein:
the wafer cleaning brush comprises a cylindrical shape having a circular bottom and a height, and
based on a cross-section cut parallel to the circular bottom, a quantity B of the plurality of protrusions satisfy Equation 2 below:
$$√ ( {P}^{∧} 2 / 4 + {( π r / B )}^{∧} 2 ) > D \qquad Equation 2$$
wherein P is the pitch of the plurality of protrusions in the length direction of the brush body, D is the width of each of the plurality of protrusions in the length direction of the brush body, and r is a radius of the brush body.

11. The wafer cleaning brush of claim 10, wherein the quantity B of the plurality of protrusions is in a range of 12 to 20.

12. The wafer cleaning brush of claim 1, wherein an interval of the plurality of protrusions in the length direction of the brush body is in a range of 5 mm to 8 mm.

13. A wafer cleaning device comprising:
a pair of brushes respectively disposed on an upper surface of a wafer and a lower surface of the wafer,
wherein each of the pair of brushes comprises:
a rotatable core;
a brush body surrounding an outer circumferential surface of the core; and
a plurality of protrusions each disposed on a surface of the brush body and comprising a circular horizontal cross-section,
wherein each of the plurality of protrusions comprises a width measured in a length direction of the brush body,
wherein a pitch of the plurality of protrusions in the length direction of the brush body is in a range of 11 mm to 15 mm, and
wherein, for each of the plurality of protrusions, a value obtained by dividing the width of the protrusion by the pitch is in a range of 0.505 to 0.525.

14. The wafer cleaning device of claim 13, wherein:
the brush body comprises a cylindrical shape having a circular bottom and a height, and
based on a cross-section cut parallel to the bottom, a quantity of the plurality of protrusions is in a range of 12 to 20.

15. The wafer cleaning device of claim 13, wherein a height of each of the plurality of protrusions is in a range of 1 mm to 5 mm.

16. A wafer cleaning method comprising:
providing a wafer having undergone a chemical mechanical planarization process;
disposing a wafer cleaning brush on an upper surface of the wafer, wherein the wafer cleaning brush includes a plurality of protrusions on a surface of the wafer cleaning brush;
supplying a cleaning composition to the upper surface of the wafer; and
removing particles on the upper surface of the wafer by bringing the plurality of protrusions into contact with the upper surface of the wafer,
wherein in the removing of the particles, the wafer and the wafer cleaning brush respectively rotate, and a maximum value of the contact frequency between the plurality of protrusions and the wafer surface is less than or equal to 0.90.

17. The wafer cleaning method of claim 16, wherein a maximum value of the contact frequency between the plurality of protrusions and the wafer surface is in a range of 0.50 to 0.80.

18. The wafer cleaning method of claim 16, wherein:
a value obtained by dividing a maximum value of the contact frequency between the plurality of protrusions and the wafer surface by a minimum value of the contact frequency is in a range of 110 to 155.

19. The wafer cleaning method of claim 16, wherein a rotation speed of the wafer is in a range of 1 rpm to 150 rpm.

20. The wafer cleaning method of claim 16, wherein a rotation speed of the wafer cleaning brush is in a range of 1 rpm to 400 rpm.
